(19) United States
(12) Patent Application Publication
(10) Pub. No.: US 2024/0099164 A1
(43) Pub. Date: Mar. 21, 2024

(54) PHASE CHANGE MEMORY CELL

(71) Applicant: Commissariat à I'Énergie Atomique et aux Énergies Alternatives, Paris (FR)

(72) Inventors: Gabriele Navarro, Grendole Cedex 9 (FR); Guillaume Bourgeois, Grendole Cedex 9 (FR); Marie-Claire Cyrille, Grendole Cedex 9 (FR)

(73) Assignee: Commissariat à I'Énergie Atomique et aux Énergies Alternatives, Paris (FR)

(21) Appl. No.: 18/467,640

(22) Filed: Sep. 14, 2023

(30) Foreign Application Priority Data
Sep. 15, 2022 (FR) 2209299

(51) Int. Cl. H10N 70/20; H10B 63/00; H10N 70/00

(52) U.S. Cl. CPC H10N 70/231; H10B 63/30; H10N 70/021; H10N 70/8413; H10N 70/8613; H10N 70/883; H10N 70/8845

(57) ABSTRACT

A phase change memory cell including: a first layer in a phase change material; a heating element located under the first layer; a second insulating layer coating a side of the heating element; and a third insulating layer interposed between the first and second layers, in a material having a density higher than that of the material of the second layer.

### CROSS REFERENCE TO RELATED APPLICATIONS

This application claims priority to French application number 2209299, filed Sep. 15, 2022, the contents of which is incorporated by reference in its entirety.

### TECHNICAL FIELD

The present disclosure relates generally to electronic devices, and more specifically memory devices comprising memory cells based on a phase change material, also called phase change memories.

### BACKGROUND ART

In a phase change memory cell, the phase change material can, under the effect of heat, alternate between a crystalline phase, electrically conducting, and an amorphous phase, electrically insulating. The crystalline and amorphous phases of the phase change material of a memory cell enable two memory states to be defined for that cell, for example respectively corresponding to the logical values 1 and 0. The heat required for the phase change is generally produced by the Joule heating, for example by means of a heating element located near the phase change material, through which passes an electrical current resulting from a voltage pulse applied between conduction terminals of the heating element.

### SUMMARY OF INVENTION

To obtain phase change memory cells with an increased energy efficiency, it would be desirable to optimize the thermal performance of current phase change memory cells, so that the electrical energy required to heat the phase change material is as low as possible. Advantageously, this would enable memory devices incorporating such cells to have an electrical consumption less than current phase change memory devices.

One embodiment addresses all or some of the drawbacks of known memory cells based on phase change materials and known memory devices incorporating such cells.

To achieve this, one embodiment provides a phase change memory cell comprising:
a first layer in a phase change material;
a heating element located under the first layer;
a second insulating layer coating a side of the heating element; and
a third insulating layer interposed between the first and second layers, in a material having a density higher than that of the material of the second layer.

According to one embodiment, the second layer is in silicon carbide or silicon carbonitride.

According to one embodiment, the third layer is in silicon carbide, in silicon nitride, in silicon carbonitride, in germanium nitride, in carbon nitride or in carbon.

According to one embodiment, the third layer is in the same material as the second layer.

According to one embodiment, the second and third layers are in silicon carbide.

According to one embodiment, the second and third layers are in silicon nitride.

According to one embodiment, the cell further comprises a first conduction electrode located under and in contact with one face of the heating element opposite to the first layer and a second conduction electrode located on and in contact with one face of the first layer opposite to the heating element.

According to one embodiment, the heating element is L-shaped.

According to one embodiment, the cell further comprises a stack comprising a fourth encapsulation layer coating the side faces of the first, second and third layers and a fifth encapsulation layer having a lower density than that of the fourth layer.

According to one embodiment, the cell further comprises a sixth encapsulation layer coating the fifth layer and having a density higher than that of the fifth layer.

One embodiment provides a manufacturing method of a phase change memory cell comprising the following successive steps:
a) depositing, on a substrate, a first insulating layer and a second insulating layer coating the first insulating layer, the second insulating layer being in a material having a density higher than that of the material of the first insulating layer;
b) forming, in a trench extending through the first and second insulating layers, a heating element having a side coated with the first and second insulating layers; and
c) depositing, on the side of the second insulating layer, a third layer in a phase change material.

According to one embodiment, the method further comprises, between steps b) and c), successive steps of depositing a fourth encapsulation layer coating the side faces of the first, second and third layers and a fifth encapsulation layer coating the fourth layer and having a lower density than that of the fourth layer.

According to one embodiment, the method further comprises, after depositing the fifth layer and before depositing the third layer, a step of depositing a sixth encapsulation layer coating the fifth layer and having a density higher than that of the fifth layer.

Furthermore, one embodiment provides a phase change memory cell comprising:
a first layer in a phase change material;
a heating element located under the first layer;
a second insulating layer coating a side of the heating element; and
a first stack comprising a third encapsulation layer coating the side faces of the second layer and a fourth encapsulation layer coating the third layer and being in a material having a lower density than that of the material of the third layer.

According to one embodiment, the fourth layer is coated with a second stack comprising alternating encapsulation layers having densities substantially equal to those of the third and fourth layers.

According to one embodiment, the fourth layer is coated with a second stack comprising successive encapsulation layers having densities substantially decreasing, lower than that of the fourth layer.

According to one embodiment, the successive encapsulation layers of the second stack are in a same material.

According to one embodiment, the cell further comprises a sixth encapsulation layer, coating the fourth layer or the second stack, the sixth layer having a density higher than that of the fourth layer.

According to one embodiment, the cell further comprises a first conduction electrode located under and in contact with one face of the heating element opposite to the first layer and a second conduction electrode located on and in contact with one face of the first layer opposite the heating element.

According to one embodiment, the cell further comprises a third stack comprising a seventh encapsulation layer coating the side faces of the first layer and of the second conduction electrode and an eighth encapsulation layer coating the seventh layer and having a lower density than that of the seventh layer.

According to one embodiment, the cell further comprises a ninth layer interposed between the first and second layers and having a density higher than that of the second layer, the second layer being in silicon carbide or silicon carbonitride.

According to one embodiment, the ninth layer is in silicon carbide, in silicon nitride or in silicon carbonitride and has a density higher than that of the second layer.

According to one embodiment, the ninth layer is in germanium nitride, in carbon nitride or in carbon.

One embodiment provides a manufacturing method of a phase change memory cell comprising the following successive steps:
a) depositing, on a substrate, at least one first thermally insulating layer;
b) forming, in a trench extending through said at least one first layer, a heating element having a side coated with said at least one first layer; and
c) forming a first stack comprising a second encapsulation layer coating the side faces of said at least one first layer and a third encapsulation layer coating the second layer, the third layer being in a material having a lower density than that of the material of the second layer.

According to one embodiment, the method further comprises, after step c), a step d) of depositing a fourth encapsulation layer coating the third layer and having a density higher than that of the third layer.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIGS. 1A and 1B are cross sectional views, partially and schematically illustrating an example of a memory device comprising memory cells based on a phase change material;

FIG. 2A, FIG. 2B, FIG. 2C, FIG. 2D, FIG. 2E, FIG. 2F, FIG. 2G, FIG. 2H and FIG. 2I are cross sectional views, partially and schematically illustrating a manufacturing method of a memory device comprising memory cells based on a phase change material according to an embodiment; and

FIGS. 3A and 3B are cross sectional views, partially and schematically illustrating a memory device comprising memory cells based on a phase change material according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the control elements and circuits of the phase change memory cells of the memory devices described, which may include elements for selection and electrical connection, are not detailed, the embodiments described being compatible with the usual control elements and circuits of phase change memory cells.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless specified otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

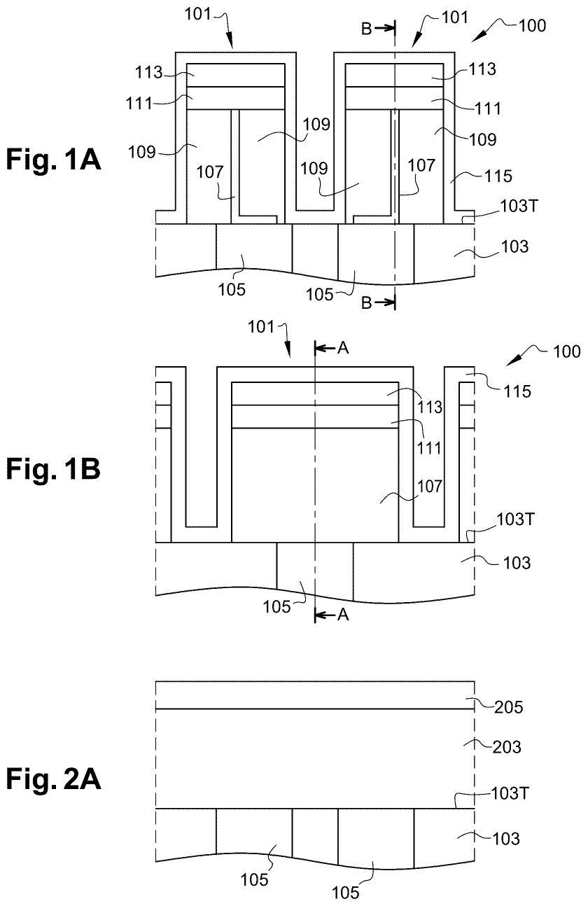

FIG. 1A and FIG. 1B are cross sectional views, respectively along the plane AA of FIG. 1B and along the plane BB of FIG. 1A, illustrating schematically and partially an example of a memory device 100 comprising memory cells 101 based on a phase change material, or phase change memory cells 101. The plane AA of FIG. 1B is substantially orthogonal to the plane BB of FIG. 1A.

As an example, the memory device 100 is a non-volatile memory, for example an EEPROM memory (Electrically Erasable Programmable Read-Only Memory). The programming of each memory cell 101 of the memory device 100 is for example performed after manufacturing of the device 100 and can subsequently be modified several times while being used.

In the example shown, the memory cells 101 are formed in and on a substrate 103, for example a wafer or part of a wafer of a semiconductor material, for example silicon.

In the example illustrated, each memory cell 101 comprises a connection element 105, for example a conducting via, formed in the substrate 103. The connection element 105 extends into the thickness of the substrate 103 from a face 103T of the substrate 103 (the upper face of the substrate 103, in the orientation of FIGS. 1A and 1B). As an example, the connection element 105 is in an electrically conducting material, for example a metal, for example copper (Cu) or tungsten (W), or a metal alloy, for example titanium nitride (TiN) or tantalum nitride (TaN).

In the example shown, each memory cell 101 further comprises a resistive heating element 107 located on and in contact with the connection element 105 of the cell. In this example, the heating element 107 is generally L-shaped comprising a horizontal part, extending laterally on and in contact with the upper face of the underlying connection element 105, and a vertical part, extending from one end of the horizontal part along a direction substantially orthogonal to the face 103T of the substrate 103. The heating element 107 is in an electrically conducting material. As an example, the heating element is in a metal or in a metal alloy.

In the example illustrated, the heating element 107 of each cell 101 is laterally interposed between two electrically and thermally insulating regions 109. More specifically, in this example, the insulating regions 109 coat all the side faces of the heating element 107 parallel to the plane BB of FIG. 1A together with the face of the horizontal part of the heating element 107 opposite to the face 103T of the substrate 103. In the orientation of FIGS. 1A and 1B, the upper faces of the insulating regions 109 are flush with the upper face of the vertical part of the heating element 107. As an example, the insulating region 109 is in silicon nitride (SiN).

In the example shown, each memory cell 101 further comprises a region in a phase change material 111. In the orientation of FIGS. 1A and 1B, the region in phase change material 111 coats the upper faces of the insulating regions 109 and the vertical part of the heating element 107 of the cell. As an example, the region 111 is in a so-called “chalcogenide” material, i.e. a material or alloy comprising at least one chalcogenide element, for example a material in the family of germanium telluride (GeTe) or of germanium-antimony-tellurium (GeSbTe, also known by the acronym “GST”).

In the example illustrated in FIGS. 1A and 1B, the upper face of the region in phase change material 111, in other words the face of the region 111 opposite to the substrate 103, is coated with an electrically conducting region 113. As an example, the electrically conducting region 113 is in a metal or a metal alloy, for example titanium nitride (TiN).

Although not illustrated in FIGS. 1A and 1B, the electrically conducting region 113 can be coated, on the face side opposite to the region in phase change material 111, with a dielectric region intended to confine heat within the cell 101.

In the example shown, each cell 101 further comprises an encapsulation layer 115 coating the sides of the stack composed of the insulating regions 109, the region in phase change material 111 and the electrically conducting region 113. The encapsulation layer 115 more specifically coats the side faces of the insulating regions 109, the side faces of the region in phase change material 111, and the side faces and the upper face of the conducting region 113. In the example illustrated, the encapsulation layer 115 further coats the side faces of the heating element 107 parallel to the plane of FIG. 1A, not coated with the insulating regions 109. The encapsulation layer 115 can, furthermore, as in the example illustrated in FIGS. 1A and 1B, extend between the memory cells 101. More specifically, in this example, the encapsulation layer 115 coats parts of the face 103T of the substrate 103 that are coated neither by the insulating regions 109 nor by the heating element 107.

Although not detailed in the figures, the memory cells 101 of the device 100 are for example arranged in an array. More specifically, the device 100 can for example comprise first lines, called “bit lines”, corresponding to rows of memory cells 101 parallel to each other and extending along a direction orthogonal to the plane of FIG. 1B, and second lines, called “word lines”, corresponding to rows of memory cells 101 parallel to each other and orthogonal to the bit lines.

Although not detailed in FIGS. 1A and 1B, the connection element 105 of each memory cell 101 extends for example through the substrate 103 and allows to connect the horizontal part of the overlying heating element 107 to a conduction terminal of a selection element, not shown, for example a MOS (metal-oxide-semiconductor) transistor, located on a side of a face of the substrate 103 opposite to the face 103T. The selection transistor, or selector, allows to individually select each memory cell 101 of the device 100. As an example, the selection transistors each comprise another conduction terminal connected to a node of application of a reference potential, for example the ground, and a control terminal (grid) to which is applied a control voltage which, according to its value, enables or prevents a circulation current between the conduction terminals (source and drain) of the transistor. The selection transistors of the memory cells 101 that are part of a same word line comprise for example a common gate, extending for example along a direction orthogonal to the plane of FIG. 1A.

Furthermore, all the memory cells that are part of the same bit line are for example interconnected by their conducting regions 113, by means of a common electrode not shown in FIGS. 1A and 1B.

The memory cells 101 of the memory device 100 array can store data by modifying the phase of the material composing their respective regions 111. In general, phase change materials are materials that are able to alternate between a crystalline phase and an amorphous phase under the effect of a variation in temperature, the amorphous phase having an electrical resistance greater than that of the crystalline phase. In the case of the memory cells 101, this phenomenon is used to obtain an on state allowing a current to pass between the connection element 105 and the conducting region 113, when the material of the region 111 is in the crystalline phase, and an off state, preventing a current circulation between the connection element 105 and the conducting region 113, when at least a part of the material of the region 111 is in the amorphous phase. In the present disclosure, for simplicity it is considered that the whole of region 111 is subject to the phase changes. However, in practice, phase changes may occur in only a part of the region 111, for example located on and in contact with the upper face of the heating element 107.

The on (region 111 in crystalline phase) and off (region 111 in amorphous phase) states of each memory cell 101 correspond for example respectively to the logical values 1 and 0. When the cell 101 switches between the logical states 1 and 0, the connection element 105 of the conducting region 113 undergoes for example a control voltage pulse causing current to pass through the heating element 107. This current causes, through the Joule heating followed by radiation and/or conduction to the interior of the structure of the cell 101, an increase in temperature of the region 111 from its lower face, located facing the heating element 107.

More specifically, to make the memory cell switch from the logical state 1 to the logical state 0, the region 111 is heated by means of the heating element 107, for example to a temperature T1 and for a duration d1. The temperature T1 and the duration d1 are chosen so as to cause a phase change in the material of the region 111 from the crystalline phase to the amorphous phase. The temperature T1 is for example higher than the melting temperature of the phase change material. As an example, the temperature T1 is between 600 and 1,000° C. and the duration d1 is less than 500 ns.

Conversely, to make the memory cell 101 switch from the logical state 0 to the logical state 1, the region 111 is heated by means of the heating element 107, for example to a temperature T2 lower than the temperature T1 and for a duration d2 longer than the duration d1. The temperature T2 and the duration d2 are chosen so as to cause a phase change in the material of the region 111 from the amorphous phase to the crystalline phase. The temperature T2 is for example higher than the melting temperature of the region 111. As an example, the temperature T2 is substantially equal to the temperature T1 and the duration d2 is shorter than 1 μs.

After manufacturing of the device 100 and before operations of writing, or programming, are carried out, the region in phase change material 111 of each memory cell 101 is for example in a crystalline phase. In other words, the memory device 100 is, before writing, in an initial state where all its cells 101 contain the same logical value (the value 1, in this example). Data storage operations can then be carried out in the memory device 100, by operating a phase change in the regions 111 of part of the memory cells 101 from the crystalline phase to the amorphous phase, corresponding in this example to a logical value 0, while the regions 111 of the other part of the cells 101 are held in their initial state, in other words in the crystalline phase corresponding in this example to the logical value 1.

To read one of the phase change memory cells 101 of the device 100, the cell is selected by biasing the gate of the associated selection transistor. A current circulation, with a sufficiently low value to avoid involuntary phase change, is then generated in the cell 101 by applying a difference in potential between the conduction region 113 and the connection element 105. An electrical resistance, between the conducting region 113 and the connection element 105, can then be measured. This electrical resistance reflects the logical value, 0 or 1, previously memorized in the memory cell 101.

Although this has not been detailed in FIGS. 1A and 1B, the device 100 can comprise other layers, for example layers in dielectric materials, placed on the side of the face 103T of the substrate 103.

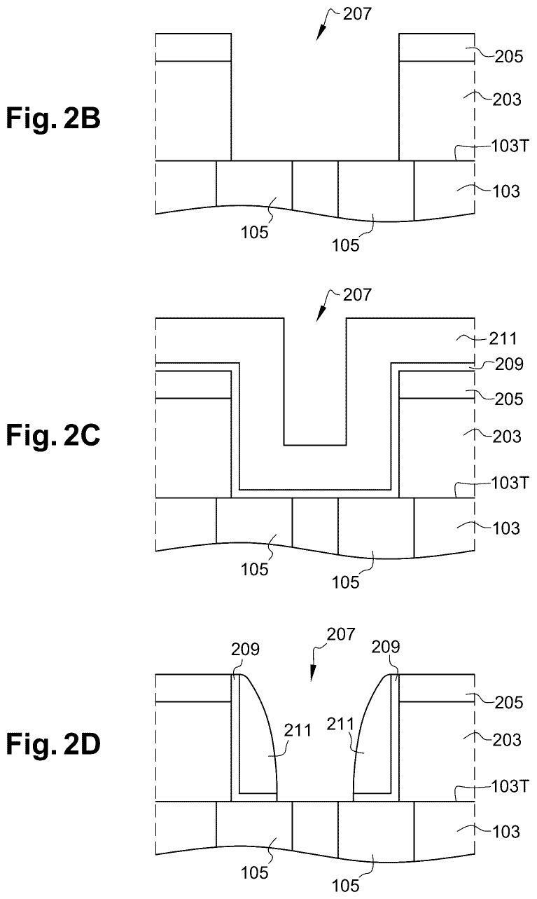

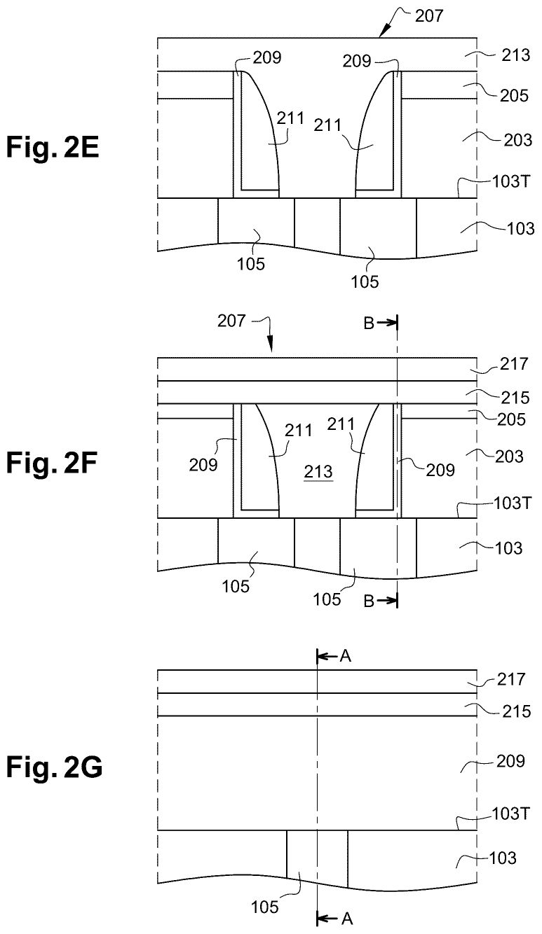

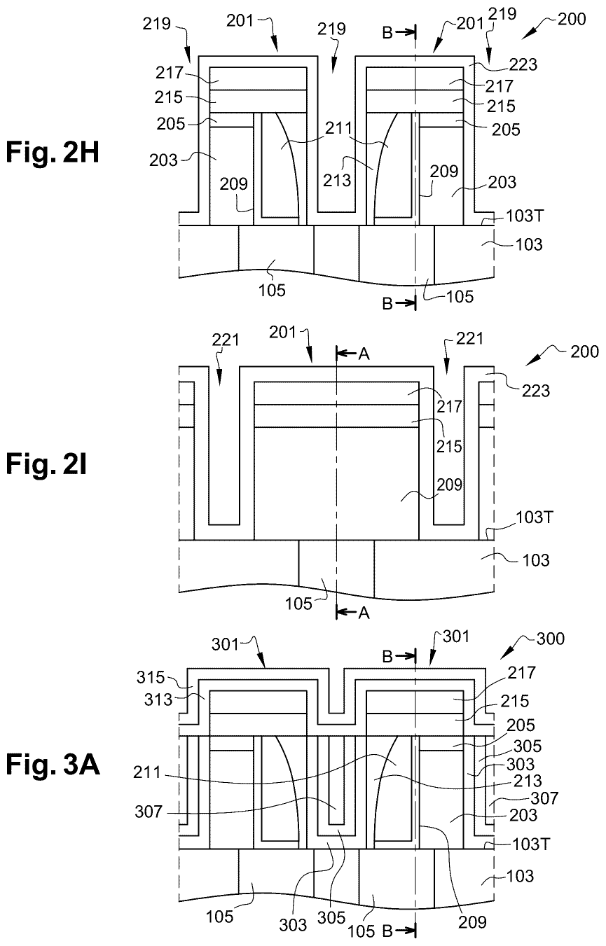

FIG. 2A, FIG. 2B, FIG. 2C, FIG. 2D, FIG. 2E, FIG. 2F, FIG. 2G, FIG. 2H and FIG. 2I are cross sectional views, partially and schematically illustrating a manufacturing method for a memory device 200 comprising memory cells 201 based on a phase change material according to an embodiment.

The memory device 200 in FIGS. 2A to 2I comprises elements in common with the memory device 100 in FIGS. 1A and 1B. These elements will not be detailed again hereafter.

FIG. 2A is a cross sectional view illustrating more specifically a structure obtained after a step of depositing, on the side of the face 103T of the substrate 103, a stack of thermally insulating layers 203 and 205. In the example shown, the insulating layer 203 coats the upper face 103T of the substrate 103 and the upper face of the connection elements 105 that are flush with the face 103T. In this example, the insulating layer 205 coats the face of the insulating layer 203 opposite to the substrate 103 (the upper face of the insulating layer 203, in the orientation of FIG. 2A).

According to one embodiment, the insulating layer 203 is a material with a lower density than the material of the insulating layer 205. The insulating layer 203 is for example in silicon carbide (SiC) or in silicon carbonitride (SiCN).

The insulating layer 205 is for example in silicon nitride (SiN), in silicon carbonitride, in germanium nitride (GeN), in carbon nitride (CN) or in carbon (C). As a variant, the insulating layers 203 and 205 are both in silicon carbide (SiC) or in silicon nitride (SiN), and the insulating layer 205 has a density higher than that of the insulating layer 203. In this case, the layer 203 has for example a density between 0.5 and 1.5 g/cm³ and the layer 205 has a density higher than 2 g/cm³. As an example, the insulating layer 203 has a thickness between 50 nm and 150 nm, for example equal to around 80 nm, and the insulating layer 205 has a thickness between 5 nm and 50 nm, for example equal to around 20 nm.

The layers 203 and 205 are for example both electrically insulating.

FIG. 2B is a cross sectional view illustrating a structure obtained after a step of forming trenches 207 in the insulating layers 203 and 205. For the sake of simplicity, a single trench 207 is shown in FIG. 2B.

In the example shown, the trench 207 extends from the upper face of the layer 205 down to the face 103T of the substrate 103, completely extending though the layers 203 and 205. In this example, the parts of the upper faces of two adjacent connection elements 105 together with a part of the face 103T of the substrate 103 located between the two connection elements 105 are exposed at the bottom of the trench 207.

The trenches 207 are for example substantially parallel to each other and extend along a direction substantially orthogonal to the plane of FIG. 2B. The trenches 207 laterally separate the separated parts of layers 203 and 205. In this example, the parts of layers 203 and 205 separated by the trenches 207 are substantially parallel to each other and extend along a direction substantially orthogonal to the plane of FIG. 2B.

As an example, the trenches 207 are formed by photolithography followed by etching.

FIG. 2C is a cross sectional view illustrating a structure obtained after a step of depositing, on the side of the face 103T of the substrate 103, an electrically conducting layer 209 coated with an electrically insulating layer 211.

In the example shown, the electrically conducting layer 209 coats the walls and the bottom of the trenches 207 and extends laterally on and in contact with the upper face of the layer 205. More specifically, in this example, the electrically conducting layer 209 coats the sides and upper face of the parts of layer 205 remaining after formation of the trenches 207, the sides and parts of the layer 203 remaining after the formation of the trenches 207 and the parts of the upper faces of the connection elements 105 and of the face 103T of the substrate 103 previously exposed at the bottom of the trenches 207. The insulating layer 211 coats the face of the conducting layer 209 opposite to the substrate 103 (the upper face of the conducting layer 209, in the orientation of FIG. 2C).

As an example, the insulating layer 209 has a thickness between 1 nm and 20 nm, for example equal to around 3 nm, and the insulating layer 211 has a thickness between 5 nm and 100 nm, for example equal to around 20 nm.

In the example illustrated in FIG. 2C, the layers 209 and 211 do not completely fill the trench 207. This example is however not limiting, and the stack formed by the layers 209 and 211 may completely fill the trench 207.

As an example, the conducting layer 209 is in a metal or a metal alloy, for example titanium nitride (TiN), tantalum nitride (TaN), titanium carbonitride (TiCN) or silicon-titanium nitride (TiSiN).

As an example, the insulating layer 211 is in silicon nitride (SiN) or silicon carbide (SiC).

FIG. 2D is a cross sectional view illustrating a structure obtained after a step of anisotropic etching of layers 209 and 211. More specifically, in the example shown, the etching rate of layers 209 and 211 is greater along a direction orthogonal to the face 103T of the substrate 103 than in directions parallel to the face 103T.

In the example illustrated in FIG. 2D, the parts of layers 209 and 211 located directly above the parts of layers 203 and 205, in other words the parts of layers 209 and 211 not located inside the trenches 207, are removed. In FIG. 2D, there remain, inside each trench 207, two separate parts of the conducting layer 209 coating opposite sides and extending on opposite parts of the bottom of the trench 207. Each part of the conducting layer 209 has a general L shape, having a horizontal part coating at least partially the upper face of one of the connection elements 105 and a vertical part coating the sides of parts of the insulating layers 203 and 205 located near the connection element 105.

Each L-shaped part of the conducting layer 209 corresponds to a heating element of a memory cell 201 of the device 200, for example identical or analogous to the heating elements 107 of the cells 101 of the device 100 previously described in relation to FIGS. 1A and 1B.

There further remains, in the example illustrated, separate parts of the insulating layer 211 located inside the Ls formed by the parts of layer 209. Each part of the insulating layer 211 coats more specifically the upper face of the horizontal part of the L formed by the part of layer 209, and the face of the vertical part of the L turned to the horizontal part of the L. In the example shown, the parts of the insulating layer 211 have a flared shape. More specifically, each part of the insulating layer 211 is wider near the horizontal part of the L formed by the associated part of layer 209 than near the end of the vertical part of the L opposite the horizontal part.

FIG. 2E is a cross sectional view illustrating a structure obtained after a step of depositing, on the side of the face 103T of the substrate 103, an electrically and thermally insulating layer 213.

In the example shown, the insulating layer 213 fills the trenches 207 and coats the upper face of the parts of the layer 205 previously exposed after the anisotropic etching step. In the example illustrated, the insulating layer 213 further coats the free faces of the parts of layers 209 and 211 remaining after the anisotropic etching step, together with the parts of the face 103T of the substrate 103 and the parts of the upper faces of the connection elements 105 previously exposed after the anisotropic etching step

The insulating layer 213 is for example in the same material as the insulating layer 203, for example in silicon carbide (SiC). As a variant, the layer 213 is in a different material from the layer 203, for example in silicon dioxide (SiO₂).

FIG. 2F and FIG. 2G are cross sectional views, respectively along the plane AA of FIG. 2G and along the plane BB of FIG. 2F, illustrating a structure obtained after a step of thinning of the insulating layer 213 then depositing, on the side of the face 103T of the substrate 103, a layer in a phase change material 215 and an electrically conducting layer 217. The plane AA of FIG. 2G is substantially orthogonal to the plane BB of FIG. 2F.

In the example shown, only the parts of the insulating layer 213 located inside the trenches 207 remain after the thinning step, the parts of the insulating layer 213 located directly above the parts of insulating layers 203 and 205 being totally removed. Furthermore, in his example, the thinning of the insulating layer 213 is carried out such as to reduce the thickness of the insulating layer 205 and the height of the parts of layers 209 and 211 remaining after the anisotropic etching step. In the example illustrated, each part of layer 209 is separated from the part of layer 213 located opposite by a thickness of material of the layer 211 equal to or greater than around 20 nm.

In the example shown, the layer in phase change material 215 coats the upper faces of the parts of layers 205, 209, 211 and 213 after thinning. In this example, the conducting layer 217 coats the upper face of the layer in phase change material 215. The compositions of the layer in phase change 215 and the conducting layer 217 are for example identical or analogous respectively to the compositions of the regions 111 and 113 of the memory cells 101 of the device 100.

As an example, the layer in phase change material 215 has a thickness between 20 nm and 100 nm, for example equal to around 50 nm, and the conducting layer 217 has a thickness between 10 nm and 100 nm, for example equal to around 50 nm.

In the example shown, the connection elements 105 and the parts of the conducting layer 217 form the conducting electrodes of the cell 201.

FIG. 2H and FIG. 2I are cross sectional views, respectively along the plane AA of FIG. 2I and along the plane BB of FIG. 2H, illustrating a structure obtained after a step of forming the trenches 219 and 221 then depositing an encapsulation layer 223 on the face 103T side of the substrate 103. The plane AA of FIG. 2I is substantially orthogonal to the plane BB of FIG. 2H.

In the example shown, the trenches 219 and 221 extend vertically in the structure, from the upper face of layer 217, to the face 103T of the substrate 103. As a variant, the trenches 219 can be omitted.

The trenches 219 are for example substantially parallel to each other and extend along a direction substantially orthogonal to the plane of FIG. 2H. The trenches 219 laterally separate the memory cells 201 that are part of the same word line of the memory device 200. Furthermore, the trenches 221 are substantially parallel to each other and extend along a direction substantially orthogonal to the plane of FIG. 2I. The trenches 221 laterally separate the memory cells 201 that are part of the same bit line of the memory device 200.

As an example, the trenches 219 and 221 are formed by photolithography followed by etching.

After the step of forming the trenches 219 and 221, the heating element and the region in phase change material of each memory cell 201 are electrically insulated from the heating elements and the regions in phase change material of the neighboring memory cells 201.

In the example shown, the encapsulation layer 223 coats the structure comprising the parts of the insulating layers 203, 205 and 213, the parts of the layer in phase change material 215 and the electrically conducting layer 217 of each memory cell 201. The encapsulation layer 223 more specifically coats all the side faces of the parts of the insulating layers 203, 205 and 213, all the side faces of the parts of the layer in phase change material 215 and all the side faces and the upper face of the parts of the conducting layer 217, together with the side faces of the L-shaped part of the layer 209 parallel to the plane of FIG. 2H, not coated with the insulating layers 203, 205 and 213. The encapsulation layer 223 can furthermore extend between the memory cells 201, as in the example illustrated in FIGS. 2H and 2I. In this example, the layer 223 more specifically coats parts of the face 103T of the substrate 103 that are coated neither by the insulating regions 203 and 213 nor by the heating element 209.

Although this has not been illustrated, the memory device 200 can further comprise selection elements, for example MOS transistors, located on a face of the substrate 103 opposite the face 103T as described previously in relation to FIGS. 1A and 1B for the memory device 100. In general, the memory device 200 functions for example identically or analogously to the device 100 of FIGS. 1A and 1B.

An advantage of the memory device 200 of FIGS. 2H and 2I stems from the fact that the layer 203 enables better thermal insulation of the memory cell 201 to be obtained and hence a more uniform heat distribution in the phase change material of layer 215, in particular compared with the memory cell 101. As a result, the electrical energy required to heat the phase change material is lower in the case of the memory device 200 than in the case of the memory device 100. This advantageously enables the memory device 200 incorporating the cells 201 to have a lower energy consumption than the memory device 100 incorporating the cells 101.

Furthermore, an advantage of the manufacturing method of the memory device 200 described hereinabove in relation to FIGS. 2A to 2I stems from the fact that it enables the insulating layer 205 to be interposed between layer 203 and the layer in phase change material 215. The insulating layer 205 advantageously enables layer 203 to be chemically stabilized while heating the layer in phase change material 215 during programming operations on the memory cell 201. More specifically, it enables the material of layer 203 not to be in contact with the material of layer 215 in the immediate neighborhood of the heating element 209, thereby preventing undesirable chemical reactions between the material of layer 203 and the material of layer 215 while heating. This enables more varied materials to be used for layer 203 and in particular those with a better thermal insulation coefficient than materials that may be placed in direct contact with layer 215 in the immediate neighborhood of the heating element 209.

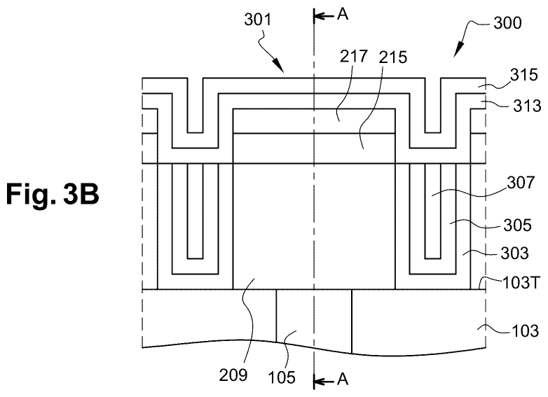

FIG. 3A and FIG. 3B are cross sectional views, respectively along the plane AA of FIG. 3B and along the plane BB of FIG. 3A, illustrating schematically and partially a memory device 300 comprising memory cells 301 based on a phase change material according to an embodiment. The plane AA of FIG. 3B is substantially orthogonal to the plane BB of FIG. 3A.

Although FIGS. 3A and 3B illustrate an example in which the stack composed of layers 203 and 205 has lateral dimensions substantially identical to those of the stack composed of layers 215 and 217, the stack composed of elements 215 and 217 can, as a variant, have lateral dimensions different from those of the stack composed of layers 203 and 205.

The device 300 in FIGS. 3A and 3B comprises elements in common with the device 200 in FIGS. 2H and 2I. These common elements will not be detailed again hereafter. The device 300 in FIGS. 3A and 3B differs from the device 200 in FIGS. 2H and 2I in that the device 300 comprises memory cells 301 comprising several encapsulation layers with different densities.

In the example shown, the memory cells 301 comprise an encapsulation layer 303 coating the structure comprising the parts of the insulating layers 203, 205 and 213 of each memory cell 301. The encapsulation layer 303 more specifically coats all the side faces of the parts of the insulating layers 203, 205 and 213 together with the side faces of the L-shaped part of layer 209 parallel to the plane of FIG. 3A not coated with the insulating layers 203, 205 and 213. The encapsulation layer 303 can further extend between the memory cells 301, as in the example illustrated in FIGS. 3A and 3B. In this example, the layer 303 more specifically coats the parts of the face 103T of the substrate 103 that are coated neither by the insulating regions 203 and 213 nor by the heating element 209.

According to one embodiment, the encapsulation layer 303 is coated with at least one other encapsulation layer 305 (a single other encapsulation layer 305, in the example shown) in a material with a density lower than that of layer 303. As an example, the layer 305 is in the same material as layer 303, for example silicon carbide, but with a lower density than that of layer 303. As a variant, the layer 305 is in a different material from layer 303. As an example, the encapsulation layers 303 and 305 are respectively in silicon nitride (SiN) and in silicon carbide (SiC).

In the example shown, a dielectric filling material 307 coats the encapsulation layer 305 and fills the free spaces between the memory cells 301. In this example, the filling material 307 is flush with the upper face of the insulating layers 205 and 213.

In the example illustrated in FIGS. 3A and 3B, the memory cells 301 comprise another encapsulation layer 313 coating the structure comprising the parts of the layer in phase change material 215 and the electrically conducting layer 217 of each memory cell 301. The encapsulation layer 223 more specifically coats all the side faces of the parts of the phase change material 215 and all the side faces and upper face of the parts of the conducting layer 217. The encapsulation layer 313 can further extend between the memory cells 301, as in the example illustrated in FIGS. 3A and 3B. In this example, the layer 313 more specifically coats the upper faces of the encapsulation layers 303 and 305 and of the filling material 307.

In the example shown, the encapsulation layer 313 is coated with at least one other encapsulation layer 315 (a single other encapsulation layer 315, in the example shown) in a material with a lower density than layer 313. As an example, the layer 315 is in the same material as layer 313, for example silicon carbide, but with a lower density than that of layer 313. As a variant, the layer 315 is in a different material from layer 313. As an example, the encapsulation layers 313 and 315 are respectively in the same materials and have respectively the same densities as the encapsulation layers 303 and 305.

The device 300 is for example obtained by a manufacturing method analogous to that of the device 200 described hereinabove in relation to FIGS. 2A to 2I. As an example, the heating elements 209 of the memory cells 301 are individualised after depositing the insulating layer 213, then the encapsulation layers 303 and 305 and the filling material 307 are deposited on the structure on the side of the upper face 103T of the substrate 103. The encapsulation layers 303 and 305, the filling material 307 and the insulating layer 213 are then thinned until the insulating layer 205 is reached, and the layer 205 can also be thinned during this step. The layer in phase change material 215 and the conducting layer 217 can then be deposited then structured, for example by photolithography followed by etching, so as to individualise the layer in phase change material 215 and the conducting layer 217 of the memory cells 301. Finally, the encapsulation layers 313 and 315 can be successively deposited on the structure on the side of the face 103T of the substrate 103.

Although there has been described, in relation to FIGS. 3A and 3B, an example in which the encapsulation layers 303 and 305 and the filling material 307 are deposited before the layer in phase change material 215, as a variant the encapsulation layers 303 and 305 could be deposited after the layer in phase change material 215, for example after depositing the layer 217. In this case, the encapsulation layers 313 and 315 can be omitted, the stack of encapsulation layers 303 and 305 then replacing the encapsulation layer 223 in FIGS. 2H and 2I.

An advantage of the memory device 300 of FIGS. 3A and 3B stems from the fact that the stack of encapsulation layers 303 and 305 enables better thermal insulation of the memory cell 301 to be obtained and hence a more uniform heat distribution in the phase change material of layer 215, in particular compared with the memory cell 101. As a result, the electrical energy required to heat the phase change material is lower in the case of the memory device 300 than in the case of the memory device 100. This advantageously enables the memory device 300 incorporating the cells 301 to have a lower energy consumption than the memory device 100 incorporating the cells 101.

Furthermore, an advantage of the memory device 300 in FIGS. 3A and 3B is that the encapsulation layer 303, respectively 313, of higher density, is interposed between the layer 305, respectively 315, of lower density, and the layer 215 in phase change material in the neighborhood of the hottest point of the layer 215, i.e. in the neighborhood of the surface of layer 215 in contact with the heating element 209. The encapsulation layer 303, respectively 313 thus enables layer 305, respectively 315 to be chemically stabilized while heating the layer in phase change material 215 during programming operations on the memory cell 301. More specifically, this prevents undesirable chemical reactions between the material of layer 305, respectively 315 and the material of layer 215 during heating.

Although stacks each composed of only two encapsulation layers 303, 313 and 305, 315 have been illustrated, it would be possible, as a variant:
to coat the encapsulation layer 305, respectively 315, with another encapsulation layer with a lower density than that of the encapsulation layer 305, respectively 315, for example a layer in silicon carbide less dense than the layer 305, respectively 315;
to coat the encapsulation layer 305, respectively 315, with another encapsulation layer with a density higher than that of the encapsulation layer 305, respectively 315, for example a layer in silicon nitride or a layer in silicon carbide more dense than layer 305, respectively 315;
to coat the encapsulation layer 305, respectively 315 with another stack comprising alternating encapsulation layers of the type of layers 303 and 305, respectively 313 and 315, that can be terminated by a layer with a density substantially equal to that of the encapsulation layer 303, respectively 313, for example a layer in silicon nitride; or
to coat the encapsulation layer 305, respectively 315, with another stack of encapsulation layers, in different materials or the same material, with lower densities than those of layer 305, respectively 315, and decreasing as the distance from the layer 305, respectively 315, increases, for example such as to obtain an encapsulation layer in a single material, for example silicon carbide, with a density gradient, said encapsulation layer being coated with an external layer with a high density, substantially equal to that of the encapsulation layer 303, respectively 313, for example a layer in silicon nitride.

Various embodiments and variants have been described. Those skilled in the art will understand that certain features of these embodiments can be combined and other variants will readily occur to those skilled in the art. In particular, the embodiment of the memory device 300 in FIGS. 3A and 3B can be transposed by those skilled in the art to the memory device 100 in FIGS. 1A and 1B.

Finally, the practical implementation of the embodiments and variants described herein is within the capabilities of those skilled in the art based on the functional description provided hereinabove. In particular, those skilled in the art are capable of choosing the deposition and etching techniques to be implemented so as to produce the various layers and regions of the devices described.

1. Phase change memory cell comprising:
a first layer in a phase change material;
a heating element located under the first layer;
a second insulating layer coating a side of the heating element; and
a third insulating layer interposed between the first and second layers, in a material having a density higher than that of the material of the second layer.

2. Cell according to claim 1, wherein the second layer is in silicon carbide or in silicon carbonitride.

3. Cell according to claim 1, wherein the third layer is in silicon carbide, in silicon nitride, in silicon carbonitride, in germanium nitride, in carbon nitride or in carbon.

4. Cell according to claim 1, wherein the third layer is in the same material as the second layer.

5. Cell according to claim 4 wherein the second and third layers are in silicon carbide.

6. Cell according to claim 1 wherein the second and third layers are in silicon nitride.

7. Cell according to claim 1, further comprising a first conduction electrode located under and in contact with one face of the heating element opposite the first layer and a second conduction electrode located on and in contact with one face of the first layer opposite the heating element.

8. Cell according to claim 1, wherein the heating element is L-shaped.

9. Cell according to claim 1, further comprising a stack comprising a fourth encapsulation layer coating the side faces of the first, second and third layers and a fifth encapsulation layer coating the fourth layer and having a lower density than that of the fourth layer.

10. Cell according to claim 9, further comprising a sixth encapsulation layer coating the fifth layer and having a density higher than that of the fifth layer.

11. Manufacturing method of a phase change memory cell comprising the following successive steps:
a) depositing, on a substrate, a first insulating layer and a second insulating layer coating the first insulating layer, the second insulating layer being in a material having a density higher than that of the material of the first insulating layer;
b) forming, in a trench extending through the first and second insulating layers, a heating element having a side covered by the first and second insulating layers; and
c) depositing, on the side of the second insulating layer, a third layer in a phase change material.

12. Method according to claim 11, further comprising, between steps b) and c), successive steps of depositing a fourth encapsulation layer coating the side faces of the first, second and third layers and of a fifth encapsulation layer coating the fourth layer and having a lower density than that of the fourth layer.

13. Method according to claim 12, further comprising, after depositing the fifth layer and before depositing the third layer, a step of depositing a sixth encapsulation layer coating the fifth layer and having a density higher than that of the fifth layer.
